(19) United States
(12) Patent Application Publication
(10) Pub. No.: US 2025/0311151 A1
(43) Pub. Date: Oct. 2, 2025

(54) COOLING DEVICE

(71) Applicant: NIDEC CORPORATION, Kyoto (JP)

(72) Inventors: Genki HORIGUCHI, Kyoto (JP); Takaya OKUNO, Kyoto (JP)

(21) Appl. No.: 19/088,320

(22) Filed: Mar. 24, 2025

(30) Foreign Application Priority Data
Mar. 29, 2024 (JP) 2024-056147

(51) Int. Cl. H05K 7/20

(52) U.S. Cl. CPC H05K 7/20254; H05K 7/20272

(57) ABSTRACT

A cooling device comes into thermal contact with a first heat generating component, and includes a first component and a second component. The first component defines a liquid flow path. The second component is connected to one side in the first direction with respect to the first component to define the flow path. The first component includes a reservoir. The reservoir includes a wall surface opposing a side opposite to an edge of the first component and extending to the one side in the first direction. At least a portion of the reservoir is closer to an edge of the first component than the flow path.

### CROSS-REFERENCE TO RELATED APPLICATIONS

The present application claims priority under 35 U.S.C. § 119 to Japanese Patent Application No. 2024-056147, filed on Mar. 29, 2024, the entire contents of which are hereby incorporated herein by reference.

### 1. FIELD OF THE INVENTION

The present disclosure relates to cooling devices.

### 2. BACKGROUND

In a conventional cold plate, a cover covers a flow path block, which is mounted on a base and through which a liquid refrigerant flows, from above. The cover is fixed to the base.

In the conventional cold plate, when the refrigerant leaks from the cover, the refrigerant easily flows to the outside of the base, and the refrigerant leaks to the outside of the cold plate, which may affect equipment located around the cold plate.

### SUMMARY

An example embodiment of a cooling device of the present disclosure comes into thermal contact with a first heat generating component. The present example embodiment of the cooling device includes a first component and a second component. The first component defines a liquid flow path. The second component is connected to one side in the first direction with respect to the first component to define the flow path. The first component includes a reservoir. The reservoir includes a wall surface opposing a side opposite to an edge of the first component and extending to the one side in the first direction. At least a portion of the reservoir is closer to an edge of the first component than the flow path.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a perspective view illustrating a cooling device according to a first example embodiment of the present disclosure.

FIG. 2 is a cross-sectional view of the cooling device taken along line II-II illustrated in FIG. 1.

FIG. 3 is a diagram illustrating a region III in FIG. 2.

FIG. 4 illustrates a portion on the other side in a second direction of the cross section of the cooling device taken along line IV-IV illustrated in FIG. 1.

FIG. 5 illustrates a portion of a cold plate on the other side in the second direction in a first modification of the cooling device according to the first example embodiment.

FIG. 6 illustrates a portion of a cold plate on the other side in the second direction in a second modification of the cooling device according to the first example embodiment.

FIG. 7 illustrates a portion of a cold plate on the other side in the second direction in a third modification of the cooling device according to the first example embodiment.

FIG. 8 is a perspective view illustrating a cooling device according to a second example embodiment of the present disclosure.

FIG. 9 is a cross-sectional view of the cooling device taken along line IX-IX illustrated in FIG. 8.

### DETAILED DESCRIPTION

Hereinafter, example embodiments of the present disclosure will be described with reference to the drawings. In the drawings, the same or corresponding parts are denoted by the same reference numerals, and the description will not be repeated. The present description appropriately describes a first direction Z, a second direction X, and a third direction Y orthogonal to one another for easy understanding. One side in the first direction Z is referred to as one side Z1 in the first direction, and the other side in the first direction Z is referred to as the other side Z2 in the first direction. One side in the second direction X is referred to as one side X1 in the second direction, and the other side in the second direction X is referred to as the other side X2 in the second direction. One side in the third direction Y is referred to as one side Y1 in the third direction, and the other side in the third direction Y is referred to as the other side Y2 in the third direction. However, the direction is defined merely for convenience of description, and the orientation during use of the exemplary cooling device of the present disclosure is not limited unless it is necessary to define the horizontal direction and the vertical direction in particular. In the present description, an “orthogonal direction” includes a substantially orthogonal direction.

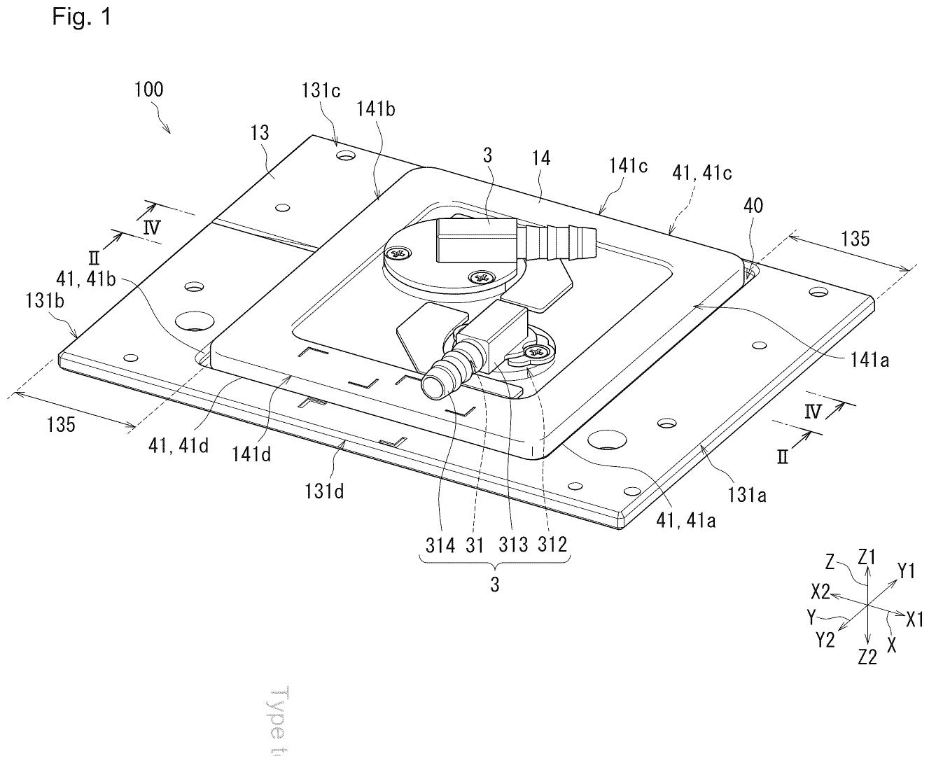

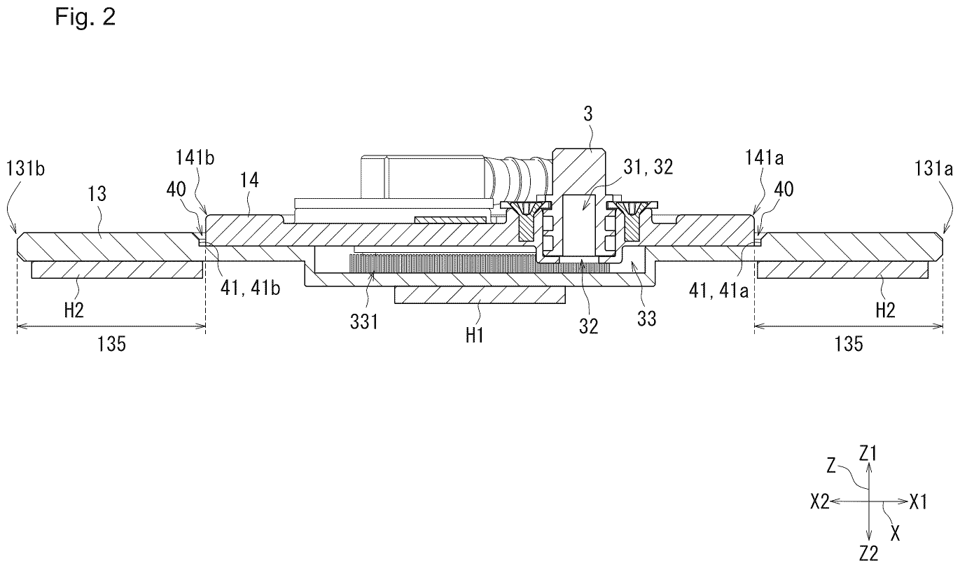

A cooling device 100 according to a first example embodiment will be described with reference to FIGS. 1 and 2. FIG. 1 is a perspective view illustrating the cooling device 100 according to the first example embodiment. FIG. 2 is a cross-sectional view of the cooling device 100 taken along line II-II illustrated in FIG. 1.

The cooling device 100 includes a cold plate 13, a cover 14, and one or more joints 3. The cold plate 13 is thermally contactable with a heat generating component. The cooling device 100 causes the refrigerant to pass through the inside of the cooling device 100, and causes heat exchange between a first heat generating component H1 (FIG. 2) and a refrigerant via the cold plate 13 to cool the first heat generating component H1. The first heat generating component H1 is located on the other side Z2 in the first direction of the cold plate 13, and is capable of coming into thermal contact with a surface of the cold plate 13 on the other side Z2 in the first direction. The cold plate 13 is made of a high thermal conductivity material. Examples of this type of material include metals such as copper and aluminum. In addition, the cold plate 13 can be manufactured from fine ceramics containing aluminum nitride or silicon carbide. The refrigerant is typically liquid. For example, the surface of the cold plate 13 on the other side Z2 in the first direction and the first heat generating component H1 are to be in contact with each other via a member having high heat conductivity such as heat grease or a heat conductive sheet, or in direct contact with each other.

The cover 14 covers the cold plate 13. Specifically, the cover 14 is connected to the cold plate 13 on the one side Z1 in the first direction, and covers a surface of the cold plate 13 on the one side Z1 in the first direction. A flow path 33 through which the refrigerant passes is formed between the cold plate 13 and the cover 14. The cover 14 is provided with a flow path 32 connected to the one side Z1 in the first direction of the flow path 33 formed between the cold plate 13 and the cover 14. The flow path 32 is formed as a through hole penetrating the cover 14 in the first direction Z. In the first example embodiment, the cold plate 13 is an example of a first component. The cover 14 is an example of a second component.

The joint 3 is detachable from the cover 14. Specifically, a portion of the joint 3 is located inside the through hole of the cover 14. In the first example embodiment, the number of the joints 3 is two. Each joint 3 is a pipe joint having the same specification. However, the present disclosure is not limited thereto, and the number of the joints 3 may be one or three or more, and the joints 3 may be pipe joints having specifications different from each other. The joint 3 is an example of a piping member.

A flow path 31 connected to the flow path 32 is formed in the joint 3. Specifically, each joint 3 includes a spigot 312, a main body 313, and a spigot 314. A portion of the spigot 312 is located inside the through hole of the cover 14. The spigot 312 has a tubular shape. The spigot 312 extends in the first direction Z in a state of being located inside the through hole of the cover 14. The outer peripheral surface of the spigot 312 has a substantially cylindrical shape.

The main body 313 connects the spigot 312 and the spigot 314. The spigot 312 is provided at one end of the main body 313. The spigot 314 is provided at the other end of the main body 313 opposite to the side where the spigot 312 is provided. An external component is connected to the spigot 314. The external component is, for example, a pipe through which a refrigerant passes.

The flow path 31 is formed inside the main body 313. The flow path 31 extends from an end 312a on the other side Z2 in the first direction of the spigot 312 to the tip of the spigot 314 while passing through the spigot 312, the main body 313, and the spigot 314. That is, a portion of the flow path 31 is formed inside a portion of the flow path 32. In the first example embodiment, the main body 313 and the spigot 314 extend in a direction different from the direction of the spigot 312. However, the present disclosure is not limited thereto, and the main body 313 and the spigot 314 may extend in the same direction (that is, the first direction Z) as that of the spigot 312.

The flow path 33 is formed of at least a surface of the cover 14 facing the other side Z2 in the first direction and a surface of the cold plate 13 facing the one side Z1 in the first direction. The flow path 33 is provided with a fin unit 331. The cold plate 13 has the fin unit 331. The fin unit 331 is provided on a surface of the cold plate 13 opposite to a surface to be brought into contact with the first heat generating component H1. The fin unit 331 includes a plurality of fins. The plurality of fins protrude from the surface opposite to the surface to be brought into contact with the first heat generating component H1 toward the one side Z1 in the first direction, and extend along the third direction Y.

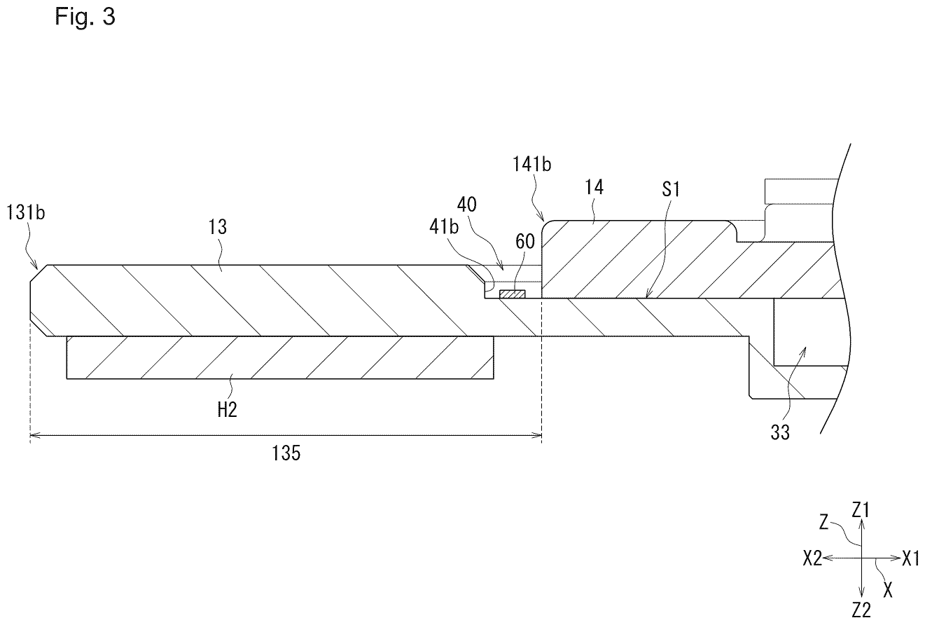

Next, the cold plate 13 and the cover 14 will be described with reference to FIGS. 1 to 3. FIG. 3 is a diagram illustrating a region III in FIG. 2. FIG. 3 representatively illustrates a portion of the cold plate 13 on the other side X2 in the second direction.

As illustrated in FIGS. 1 to 3, the cold plate 13 is a plate-like member having a substantially rectangular parallelepiped outer shape that is thin in the first direction Z. The cold plate 13 has a first edge 131a, a second edge 131b, a third edge 131c, and a fourth edge 131d each indicating an outer peripheral edge as viewed from the one side Z1 in the first direction. The first edge 131a is an edge on one side X1 in the second direction of the cold plate 13 and extends along the third direction Y. The second edge 131b is an edge on the other side X2 in the second direction of the cold plate 13 and extends along the third direction Y. The third edge 131c is an edge on one side Y1 in the third direction of the cold plate 13 and extends along the second direction X. The fourth edge 131d is an edge on the other side Y2 in the third direction of the cold plate 13 and extends along the second direction X.

In the first example embodiment, the cold plate 13 includes a reservoir 40. The reservoir 40 has a wall surface 41 facing a side opposite to an edge of the cold plate 13. Specifically, the cold plate 13 is provided with a wall surface 41a facing the other side X2 in the second direction opposite to the first edge 131a. The cold plate 13 is provided with a wall surface 41b facing the one side X1 in the second direction opposite to the second edge 131b. The cold plate 13 is provided with a wall surface 41c (not illustrated) facing the other side Y2 in the third direction opposite to the third edge 131c. The cold plate 13 is provided with a wall surface 41d (not illustrated) facing the one side Y1 in the third direction opposite to the fourth edge 131d.

The wall surface 41a, the wall surface 41b, the wall surface 41c, and the wall surface 41d extend from a connection surface S1 (FIG. 3) to the one side Z1 in the first direction of the cold plate 13. The connection surface S1 is a surface facing the one side Z1 in the first direction and to be brought into contact with the cover 14. The wall surface 41a, the wall surface 41b, the wall surface 41c, and the wall surface 41d may have a structure extending to the one side Z1 in the first direction while being inclined with respect to the second direction X or the third direction Y.

In the first example embodiment, the wall surface 41 of the reservoir 40 is located closer to the edge of the cold plate 13 than the flow path 32 and the flow path 33. As a result, for example, even when the refrigerant passing through the flow path 33 moves from the flow path 33 to the edge side of the cold plate 13 via between the connection surface of the cold plate 13 and the cover 14, the refrigerant moving to the edge side of the cold plate 13 is dammed by the wall surface 41. Accordingly, leakage of the refrigerant from the outer peripheral edge of the cold plate 13 of the cooling device 100 to the outside can be suppressed.

Specifically, the wall surface 41a of the reservoir 40 is located closer to the first edge 131a than the flow path 32 and the flow path 33. In other words, it is located on the one side X1 in the second direction with respect to the flow path 32 and the flow path 33.

The wall surface 41b of the reservoir 40 is located closer to the second edge 131b than the flow path 32 and the flow path 33. In other words, the wall surface 41b is located on the other side X2 in the second direction with respect to the flow path 32 and the flow path 33.

The wall surface 41c of the reservoir 40 is located closer to the third edge 131c than the flow path 32 and the flow path 33. In other words, the wall surface 41c is located on the one side Y1 in the third direction with respect to the flow path 32 and the flow path 33.

The wall surface 41d of the reservoir 40 is located closer to the fourth edge 131d than the flow path 32 and the flow path 33. In other words, the wall surface 41d is located on the other side Y2 in the third direction with respect to the flow path 32 and the flow path 33.

Hereinafter, the first edge 131a side with respect to the wall surface 41a may be referred to as an outer side, and the flow path 32 and the flow path 33 side with respect to the wall surface 41a may be referred to as an inner side. Similarly, the second edge 131b side with respect to the wall surface 41b may be referred to as an outer side, and the flow path 32 and the flow path 33 side with respect to the wall surface 41b may be referred to as an inner side. The third edge 131c side with respect to the wall surface 41c may be referred to as an outer side, and the flow path 32 and the flow path 33 side with respect to the wall surface 41c may be referred to as an inner side. The fourth edge 131d side with respect to the wall surface 41d may be referred to as an outer side, and the flow path 32 and the flow path 33 side with respect to the wall surface 41d may be referred to as an inner side.

In the first example embodiment, the cold plate 13 has an overhanging portion 135 that overhangs in a direction intersecting the first direction Z from an outer peripheral surface of the cover 14 along the second direction X and the third direction Y.

Typically, the cold plate 13 includes the overhanging portion 135 overhanging from a first edge 141a indicating an outer peripheral surface of the cover 14 on the one side X1 in the second direction to the one side X1 in the second direction, the overhanging portion 135 overhanging from a second edge 141b indicating an outer peripheral surface of the cover 14 on the other side X2 in the second direction to the other side X2 in the second direction, the overhanging portion 135 overhanging from a third edge 141c indicating an outer peripheral surface of the cover 14 on the one side Y1 in the third direction to the one side Y1 in the third direction, and the overhanging portion 135 overhanging from a fourth edge 141d indicating an outer peripheral surface of the cover 14 on the other side Y2 in the third direction to the other side Y2 in the third direction. That is, the overhanging portion 135 is provided to surround the entire circumference of the cover 14 in the cold plate 13. Note that the overhanging portion 135 may overhang only in a partial direction from a portion of the outer peripheral surface of the cover 14.

In the reservoir 40, the wall surface 41a, the wall surface 41b, the wall surface 41c, and the wall surface 41d are provided to the overhanging portion 135. Therefore, the reservoir 40 can be provided outside the cover 14. As a result, since the distance from the outer peripheral surface of the cover 14 to the wall surface 41 increases, the area of the region surrounded by the cover 14 and the wall surface 41 increases, and the amount of refrigerant that can be dammed by the wall surface 41 can be increased.

As illustrated in FIGS. 2 and 3, the wall surface 41 faces the outer peripheral surface of the cover 14. Specifically, the wall surface 41a faces the first edge 141a of the cover 14. The wall surface 41b faces the second edge 141b of the cover 14. The wall surface 41c faces the third edge 141c of the cover 14. The wall surface 41d faces the fourth edge 141d of the cover 14.

In this manner, the reservoir 40 is formed between the wall surface 41 and the outer peripheral surface of the cover 14. Specifically, the reservoir 40 is formed by the wall surface 41a and the first edge 141a, the wall surface 41b and the second edge 141b, the wall surface 41c and the third edge 141c, the wall surface 41d and the fourth edge 141d, and the connection surface S1.

By forming the wall surface 41 on the one side Z1 in the first direction with respect to the connection surface S1, the thickness of the cold plate 13 along the first direction Z can be reduced as compared with the case where the reservoir 40 is formed on the other side Z2 in the first direction with respect to the connection surface S1 in the cold plate 13.

For example, as illustrated in FIG. 2, the position of the end of the wall surface 41 on the one side Z1 in the first direction is located on the one side Z1 in the first direction with respect to the position of the end of the flow path 33 on the one side Z1 in the first direction. Therefore, a portion of the wall surface 41 and a portion of the cover 14 outside the wall surface 41 are located on the one side Z1 in the first direction with respect to a portion of the flow path 32.

As described with reference to FIGS. 1 to 3, the wall surface 41 surrounds the entire circumference of the cover 14. Accordingly, since the reservoir 40 is formed in the cold plate 13 so as to surround the entire circumference of the cover 14, the refrigerant is less likely to leak out of the cold plate 13 in any of the second direction X and the third direction Y.

In the first example embodiment, the cooling device 100 further includes a liquid leakage sensor 60 that detects liquid such as a refrigerant. The liquid leakage sensor 60 is located in the reservoir 40. If the refrigerant passing through the flow path 33 leaks to the outside of the cover 14, the refrigerant can be detected in the reservoir 40 by the liquid leakage sensor 60. Therefore, it is easy to detect leakage of the refrigerant before the reservoir 40 is filled with the refrigerant. Note that the liquid leakage sensor 60 may be located on the wall surface 41 of the reservoir 40, may be located on the outer peripheral surface of the cover 14, or may be located on the connection surface S1 connecting the wall surface 41 and the outer peripheral surface of the cover 14. The liquid leakage sensor 60 is an example of a detector. The operation principle of the liquid leakage sensor 60 is not particularly limited.

As illustrated in FIG. 2, the overhanging portion 135 comes into thermal contact with a second heat generating component H2 different from the first heat generating component H1. For example, the surface of the overhanging portion 135 on the other side Z2 in the first direction and the second heat generating component H2 are to be in contact with each other via a member having high heat conductivity such as heat grease or a heat conductive sheet or in direct contact with each other. Therefore, heat exchange between the cooling device 100 and each of the plurality of heat generating components becomes possible, and the plurality of heat generating components can be cooled with a simple configuration.

For example, the overhanging portion 135 and the cold plate 13 are a single member. In other words, the overhanging portion 135 is formed as a portion of the cold plate 13. Accordingly, the heat conductivity from the overhanging portion 135 to the cold plate 13 is improved.

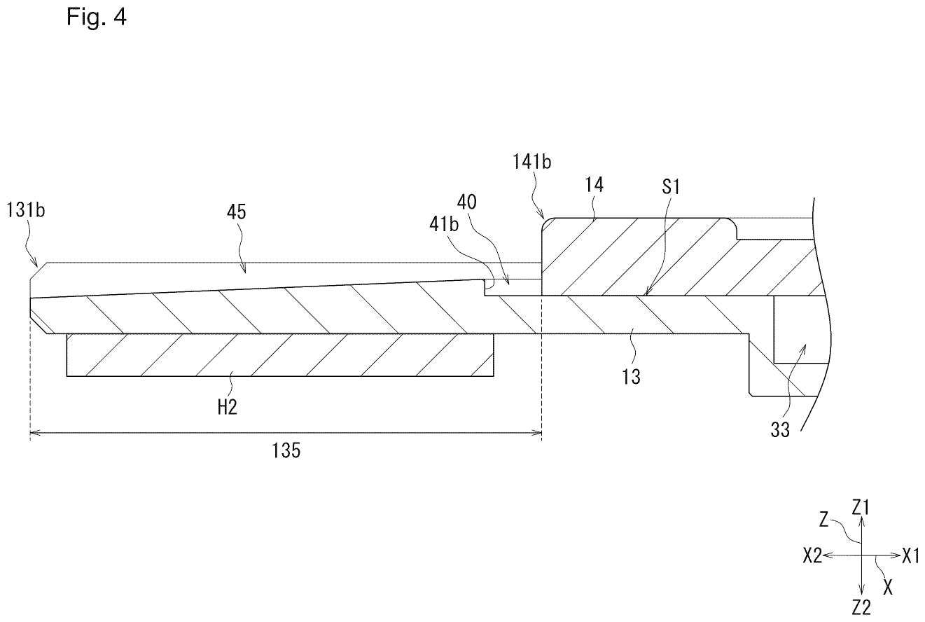

Next, a drainage channel 45 provided in the cooling device 100 of the first example embodiment will be described with reference to FIGS. 1 and 4. FIG. 4 is a diagram illustrating a portion of a cross section of the cooling device 100 on the other side X2 of the second direction other side X2, taken along line IV-IV illustrated in FIG. 1. In FIG. 4, the liquid leakage sensor 60 is omitted.

As illustrated in FIG. 4, the cold plate 13 further includes the drainage channel 45 connecting the wall surface 41b of the reservoir 40 and the second edge 131b of the cold plate 13. By providing the drainage channel 45, the liquid is guided from the reservoir 40 to a predetermined place, and the accumulated liquid is easily discharged. For example, the predetermined place is a place where an electronic component or the like including a heat generating component is not located, and the liquid hardly affects the surrounding devices. The cooling device 100 of the first example embodiment may not be provided with the drainage channel 45.

The drainage channel 45 is provided outside the wall surface 41b on the surface of the cold plate 13 facing the one side Z1 in the first direction. Typically, the drainage channel 45 is a groove that is recessed toward the other side Z2 in the first direction from a surface facing the one side Z1 in the first direction of the cold plate 13 and positioned outside the wall surface 41b, and extends in a direction intersecting the first direction Z. In the cooling device 100, the drainage channel 45 extends along the second direction X. The length (depth) of the drainage channel 45 along the first direction Z is shorter than the length (height) of the wall surface 41b along the first direction Z. That is, a step is formed between the bottom surface of the drainage channel 45 and the connection surface S1 which is the bottom of the reservoir 40. In the first example embodiment, the length (width) of the drainage channel 45 along the third direction Y is shorter than the length (width) of the wall surface 41b along the third direction Y, but the length (width) of the drainage channel 45 along the third direction Y is not particularly limited.

The liquid leakage sensor 60 may be located in the drainage channel 45. In this case, when a certain amount or more of the refrigerant is accumulated in the reservoir 40 and the refrigerant flows into the drainage channel 45, the liquid leakage sensor 60 detects liquid leakage. Therefore, when slight liquid leakage is allowed, it is also possible to give priority to continuation of operation of the device by delaying determination of liquid leakage.

For example, the drainage channel 45 is inclined to the other side Z2 in the first direction toward the edge of the cold plate 13. Specifically, in the cold plate 13, the drainage channel 45 is inclined such that the other side X2 in the second direction thereof is located closer to the other side Z2 in the first direction. Accordingly, the refrigerant easily moves from the reservoir 40 toward the second edge 131b of the cold plate 13.

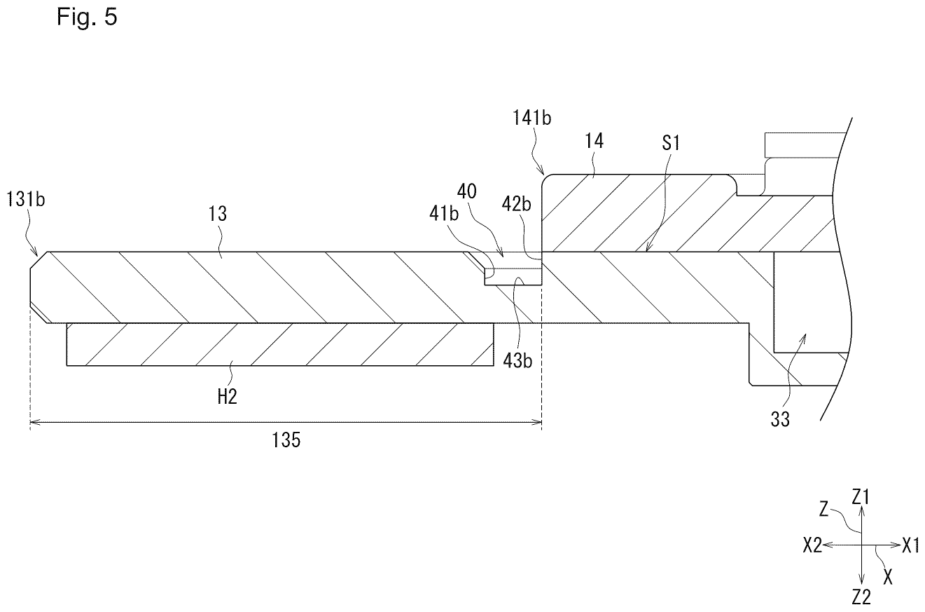

Next, a first modification of the cooling device 100 of the first example embodiment will be described with reference to FIG. 5. FIG. 5 is a diagram illustrating a portion of the cold plate 13 on the other side X2 in the second direction in a modification 1 of the cooling device 100 according to the first example embodiment.

The modification 1 of the cooling device 100 of the first example embodiment is the same as the cooling device 100 of the first example embodiment except that the shape of the reservoir 40 is different. In FIG. 4, the liquid leakage sensor 60 is omitted.

The reservoir 40 of the modification 1 of the cooling device 100 is formed of a wall surface 41, an opposing surface 42 facing the wall surface 41, and a bottom surface 43 connecting the wall surface 41 and the opposing surface 42.

Specifically, as illustrated in FIG. 5, the reservoir 40 has a wall surface 41b, an opposing surface 42b, and a bottom surface 43b. The opposing surface 42b is located on the one side X1 in the second direction with respect to the wall surface 41b, and extends from the connection surface S1 to the other side Z2 in the first direction. An end of the opposing surface 42b on the other side Z2 in the first direction is connected to the bottom surface 43b. The bottom surface 43b extends in a direction intersecting the opposing surface 42b. The bottom surface 43b is a surface facing the one side Z1 in the first direction. The wall surface 41b extends from the bottom surface 43b to the other side Z2 in the first direction. As described above, the reservoir 40 in the modification 1 of the cooling device 100 is a recess formed of the wall surface 41b, the opposing surface 42b, and the bottom surface 43b, and recessed from the connection surface S1 to the other side Z2 in the first direction. In the modification 1 of the cooling device 100, a similar reservoirs 40 are provided on three sides of the cold plate 13 other than the other side X2 in the second direction.

Therefore, as compared with the case where the wall surface is formed on the one side Z1 in the first direction with respect to the connection surface S1, the reservoir 40 can be provided while suppressing the thickness of the overhanging portion 135 in the first direction Z. In addition, by forming the reservoir 40 on the other side Z2 in the first direction with respect to the connection surface S1 that is a boundary between the cold plate 13 and the cover 14, a step is formed between the connection surface S1 and the bottom surface 43, and the liquid easily moves from the connection surface S1 to the bottom surface 43 while the liquid hardly moves from the bottom surface 43 to the connection surface S1. As a result, the liquid is easily moved away from the connection surface S1, and the liquid leaking from between the cold plate 13 and the cover 14 to the outside of the cover 14 is less likely to flow back toward the flow path 31.

The reservoir 40 in the modification 1 of the cooling device 100 of the first example embodiment is provided in the overhanging portion 135. At this time, the opposing surface 42b is provided so as not to form a step with the second edge 141b of the cover 14, for example.

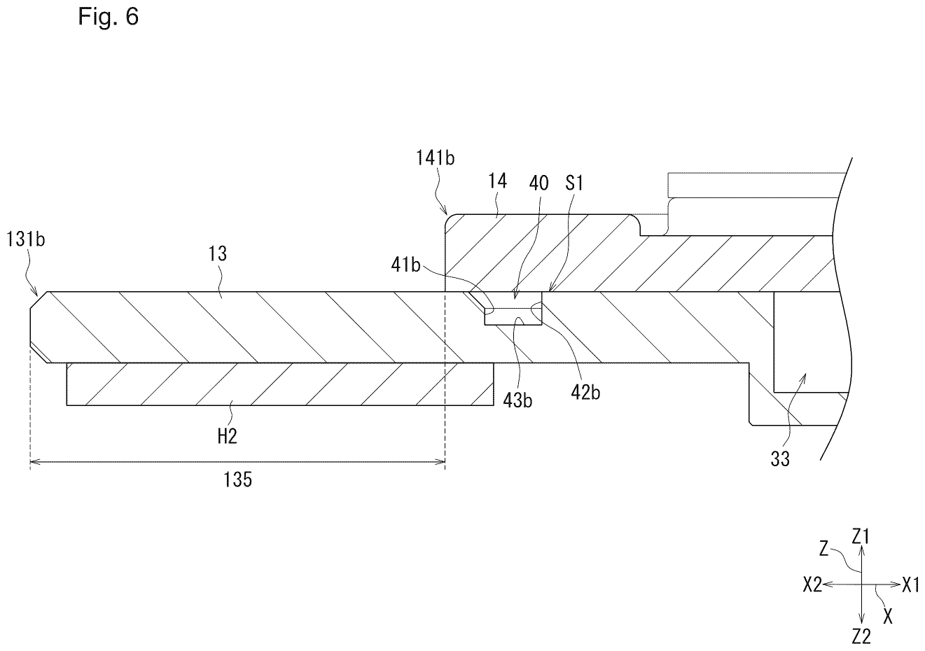

Next, a modification 2 of the cooling device 100 of the first example embodiment will be described with reference to FIG. 6. FIG. 6 is a diagram illustrating a portion of the cold plate 13 on the other side X2 in the second direction in the modification 2 of the cooling device 100 according to the first example embodiment. In FIG. 6, the liquid leakage sensor 60 is omitted.

The modification 2 of the cooling device 100 of the first example embodiment is the same as the modification 1 of the cooling device 100 of the first example embodiment except that the arrangement of the reservoir 40 is different.

As illustrated in FIG. 6, the reservoir 40 in the modification 2 of the cooling device 100 of the first example embodiment is located inside the outer peripheral surface of the cover 14. Specifically, the wall surface 41b in the modification 2 of the cooling device 100 of the first example embodiment is located on the one side X1 in the second direction with respect to the second edge 141b of the cover 14. Therefore, the bottom surface 43b connected to the wall surface 41b and the opposing surface 42b facing the wall surface 41b are also located on the one side X1 in the second direction with respect to the second edge 141b of the cover 14. That is, the reservoir 40 in the modification 2 of the cooling device 100 of the first example embodiment is covered with the cover 14 on the one side Z1 in the first direction. In other words, the reservoir 40 in the modification 2 of the cooling device 100 of the first example embodiment is not provided in the overhanging portion 135.

In addition to the modification 1 and the modification 2 of the cooling device 100 of the first example embodiment, the wall surface 41b and a portion of the bottom surface 43 may be located outside the outer peripheral surface of the cover 14, and the remaining part of the bottom surface 43 and the opposing surface 42b may be located inside the outer peripheral surface of the cover 14. In this case, the cover 14 covers a portion of the reservoir 40 on the one side Z1 in the first direction. In other words, a portion of the reservoir 40 in the modification 2 of the cooling device 100 of the first example embodiment is provided in the overhanging portion 135. By covering at least a portion of the reservoir 40 with the cover 14, for example, even when the cooling device 100 moves due to vibration or the like, the refrigerant is less likely to overflow from the reservoir 40, and leakage of the refrigerant to the outside of the cooling device 100 can be suppressed.

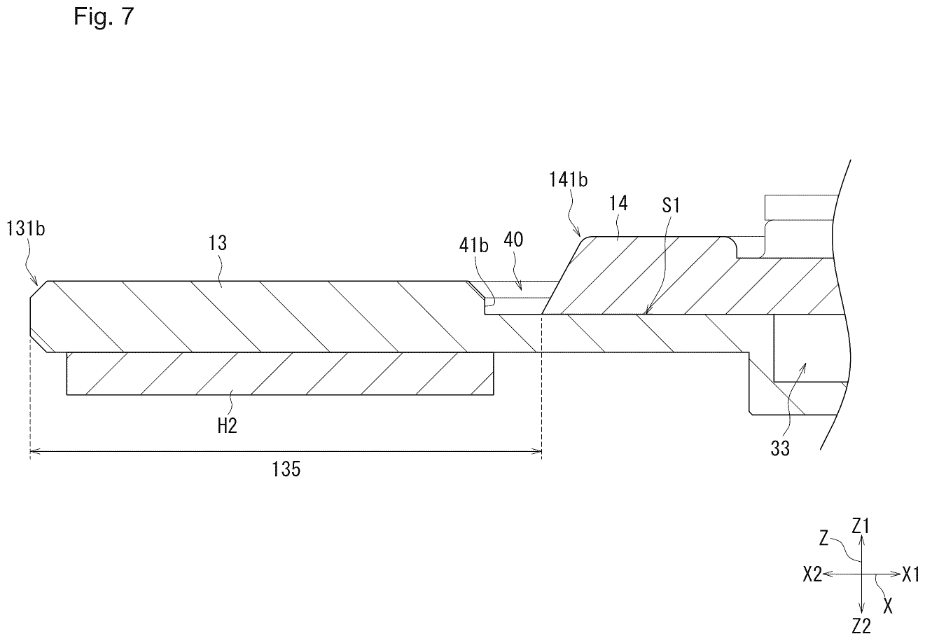

Next, a modification 3 of the cooling device 100 of the first example embodiment will be described with reference to FIG. 7. FIG. 7 is a diagram illustrating a portion of the cold plate 13 on the other side X2 in the second direction in the modification 3 of the cooling device 100 according to the first example embodiment. In FIG. 7, the liquid leakage sensor 60 is omitted.

The modification 3 of the cooling device 100 of the first example embodiment is the same as the cooling device 100 of the first example embodiment except that the shape of the outer peripheral surface of the cover 14 is different.

The outer peripheral surface of the cover 14 in the modification 3 of the cooling device 100 of the first example embodiment is inclined toward the other side Z2 in the first direction toward the outside of the cover 14. Specifically, in the cover 14 according to the modification 3 of the cooling device 100 of the first example embodiment, the second edge 141b is inclined such that the other side X2 in the second direction thereof is located closer to the other side Z2 in the first direction. As a result, for example, when the refrigerant leaks from between the cover 14 and the joint 3 or liquid other than the refrigerant adheres to the cover 14, the liquid easily moves to the cold plate 13 along the second edge 141b. If the reservoir 40 is provided outside the second edge 141b, the refrigerant is stored in the reservoir 40 and is less likely to leak from the outer peripheral edge of the cold plate 13 to the outside. In the cover 14 according to the modification 3 of the cooling device 100 of the first example embodiment, each of the first edge 141a, the third edge 141c, and the fourth edge 141d other than the second edge 141b may have the same shape as the second edge 141b or may have a shape different from the second edge 141b.

In the first example embodiment, the cooling device 100 may be provided with a sealing member such as an O-ring. For example, the sealing member is provided between the flow path 32 and the flow path 32 and the wall surface 41 in the second direction X or the third direction Y. Typically, the sealing member is located between the cold plate 13 and the cover 14 and attached to the cold plate 13 or the cover 14.

Next, a cooling device according to a second example embodiment will be described. The second example embodiment is different from the first example embodiment in the relationship between a first component and a second component. Hereinafter, the second example embodiment will be described about matters different from those in the first example embodiment, and the duplicated matters of the first example embodiment will not be described.

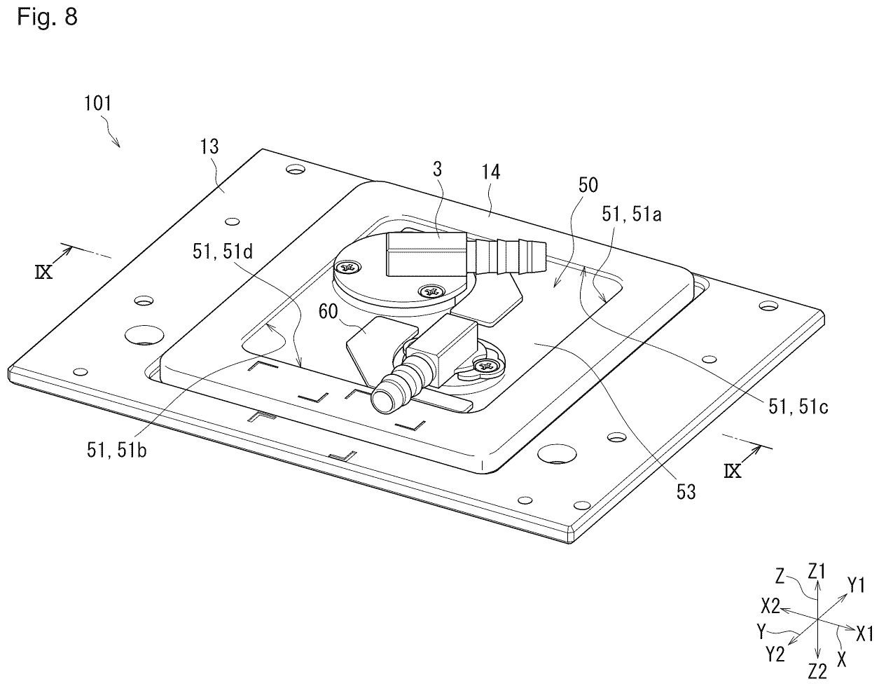

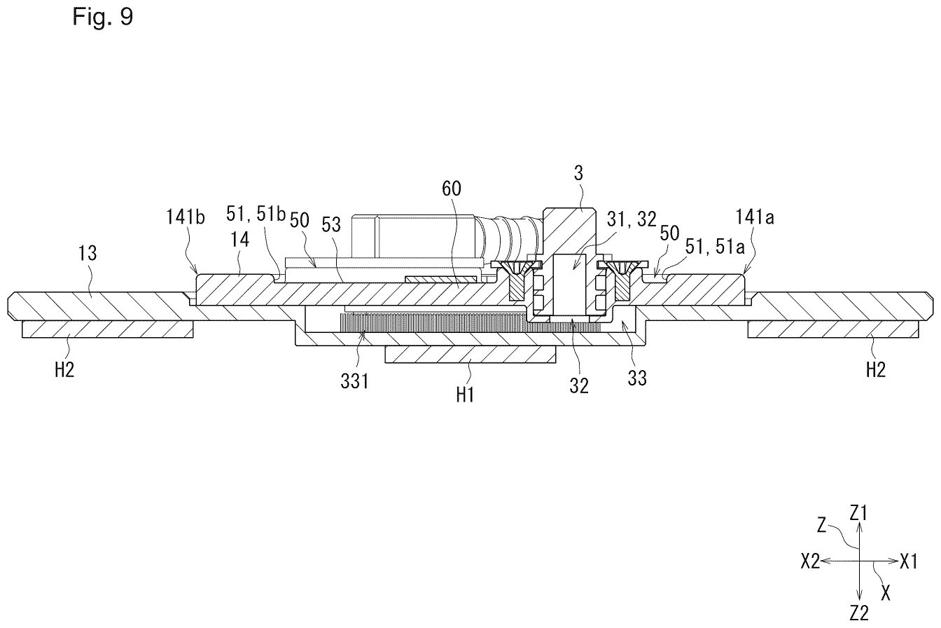

A cooling device 101 according to the second example embodiment will be described with reference to FIG. 8. FIG. 8 is a perspective view illustrating the cooling device 101 according to the second example embodiment. FIG. 9 is a cross-sectional view of the cooling device 101 taken along line IX-IX illustrated in FIG. 8.

The cooling device 101 according to the second example embodiment is the same as the cooling device 100 according to the first example embodiment except that the drainage channel 45 is not provided. In the cooling device 101 according to the second example embodiment, the cover 14 is an example of a first component. The joint 3 is an example of a second component.

The joint 3 is connected to the cover 14 on the one side Z1 in the first direction and covers at least a portion of the surface of the cover 14 on the one side Z1 in the first direction.

The cover 14 includes a reservoir 50. The reservoir 50 has a wall surface 51 facing the side opposite to the edge of the cover 14. Specifically, the cover 14 is provided with a wall surface 51a facing the other side X2 in the second direction opposite to the first edge 141a. The cover 14 is provided with a wall surface 51b facing the one side X1 in the second direction opposite to the second edge 141b. The cover 14 is provided with a wall surface 51c facing the other side Y2 in the third direction opposite to the third edge 141c. The cover 14 is provided with a wall surface 51d facing the one side Y1 in the third direction opposite to the fourth edge 141d.

The wall surface 51 of the reservoir 50 is located closer to the edge of the cover 14 than the flow path 31 and the flow path 32.

The reservoir 50 further includes a bottom surface 53. The bottom surface 53 is connected to the other side Z2 in the first direction of each of the wall surface 51a, the wall surface 51b, the wall surface 51c, and the wall surface 51d. The bottom surface 53 extends in a direction intersecting the wall surface 51a, the wall surface 51b, the wall surface 51c, and the wall surface 51d. The bottom surface 53 is a surface facing the one side Z1 in the first direction. As described above, the reservoir 50 in the cooling device 101 is a recess formed of the wall surface 51 and the bottom surface 53 and recessed from the end surface of the cover 14 on the one side Z1 in the first direction toward the other side Z2 in the first direction.

Each of the wall surface 51a, the wall surface 51b, the wall surface 51c, and the wall surface 51d faces the outer peripheral surface of the spigot 312, or faces the outer peripheral surface of the protrusion of the cover 14 protruding from the bottom surface 53 to the one side Z1 in the first direction.

In the second example embodiment, the reservoir 50 may have the same configuration as the reservoir 40 of each of the first example embodiment and the first to third modifications of the first example embodiment. The reservoir 50 of the second example embodiment may be provided in the cover 14 of the cooling device 100 of the first example embodiment.

The example embodiments of the present disclosure have been described above with reference to the drawings. However, the present disclosure is not limited to the above example embodiment, and can be implemented in various modes without departing from the gist of the present disclosure. Further, a plurality of constituent elements disclosed in the above example embodiments can be appropriately modified. For example, a certain constituent element of all constituent elements illustrated in a certain example embodiment may be added to constituent elements of another example embodiment, or some constituent elements of all constituent elements illustrated in a certain example embodiment may be removed from the example embodiment.

Further, the drawings schematically illustrate each constituent element mainly in order to facilitate understanding of the disclosure, and the thickness, length, number, interval, and the like of the illustrated constituent elements may be different from the actual ones for convenience of creation of the drawings. The configuration of each component shown in the above example embodiment is an example and is not particularly limited, and it goes without saying that various modifications can be made without substantially departing from the effects of the present disclosure.

Example embodiments of the present disclosure can have any of the configurations below.

(1) A cooling device that comes into thermal contact with a first heat generating component, the cooling device including a first component that defines a flow path for liquid, and a second component that is connected to the first component on one side in a first direction and defines the flow path, wherein the first component includes a reservoir including a wall surface opposing a side opposite to an edge of the first component and extending to the one side in the first direction, and at least a portion of the reservoir is closer to the edge of the first component than the flow path.

(2) The cooling device according to (1), wherein the first component includes an overhanging portion overhanging from an outer peripheral surface of the second component in a direction intersecting the first direction, and at least a portion of the reservoir is provided to the overhanging portion.

(3) The cooling device according to (1) or (2), wherein the wall surface opposes an outer peripheral surface of the second component.

(4) The cooling device according to any one of (1) to (3), wherein the wall surface surrounds an entire circumference of the second component.

(5) The cooling device according to any one of (1) to (4), wherein the first component includes a drainage channel connecting the reservoir and the edge of the first component.

(6) The cooling device according to (5), wherein the drainage channel is inclined to another side in the first direction toward the edge of the first component.

(7) The cooling device according to any one of (1) to (6), further including a detector to detect liquid, wherein the detector is located in the reservoir.

(8) The cooling device according to any one of (1) to (7), wherein the outer peripheral surface of the second component is inclined to another side in the first direction toward an edge of the second component.

(9) The cooling device according to any one of (2) to (8), wherein the overhanging portion comes into thermal contact with the second heat generating component.

(10) The cooling device according to any one of (1) to (9), wherein the overhanging portion and the first component are defined by a single monolithic structure.

(11) The cooling device according to any one of (1) to (10), wherein the first component includes a cold plate that comes into thermal contact with the first heat generating component, the second component includes a cover that covers the cold plate on the one side in the first direction, and the cold plate and the cover define the flow path.

(12) The cooling device according to any one of (1) to (7), further including a cold plate that comes into contact with the first heat generating component, wherein the first component includes a cover that is connected to the cold plate on the one side in the first direction and covers the cold plate on the one side in the first direction, the second component includes a pipe portion connected to the cover, and the cover and the pipe portion define the flow path.

The present disclosure is applicable to the field of cooling devices.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A cooling device that comes into thermal contact with a first heat generating component, the cooling device comprising:
a first component that defines a flow path for liquid; and
a second component that is connected to the first component on one side in a first direction and defines the flow path; wherein
the first component includes a reservoir including a wall surface opposing a side opposite to an edge of the first component and extending to the one side in the first direction; and
at least a portion of the reservoir is closer to the edge of the first component than the flow path.

2. The cooling device according to claim 1, wherein
the first component includes an overhanging portion overhanging from an outer peripheral surface of the second component in a direction intersecting the first direction; and
at least a portion of the reservoir is provided at the overhanging portion.

3. The cooling device according to claim 2, wherein the wall surface opposes an outer peripheral surface of the second component.

4. The cooling device according to claim 2, wherein the wall surface surrounds an entire circumference of the second component.

5. The cooling device according to claim 1, wherein the first component includes a drainage channel connecting the reservoir and the edge of the first component.

6. The cooling device according to claim 5, wherein the drainage channel is inclined to another side in the first direction toward the edge of the first component.

7. The cooling device according to claim 1, further comprising:
a detector to detect liquid; wherein
the detector is located in the reservoir.

8. The cooling device according to claim 2, wherein the outer peripheral surface of the second component is inclined to another side in the first direction toward an edge of the second component.

9. The cooling device according to claim 2, wherein the overhanging portion comes into thermal contact with the second heat generating component.

10. The cooling device according to claim 9, wherein the overhanging portion and the first component are portions of a single monolithic structure.

11. The cooling device according to claim 1, wherein
the first component includes a cold plate that comes into thermal contact with the first heat generating component;
the second component includes a cover that covers the cold plate on the one side in the first direction; and
the cold plate and the cover define the flow path.

12. The cooling device according to claim 1, further comprising:
a cold plate that comes into contact with the first heat generating component; wherein
the first component includes a cover that is connected to the cold plate on the one side in the first direction and covers the cold plate on the one side in the first direction;
the second component includes a pipe connected to the cover; and
the cover and the pipe define the flow path.
